(19) United States
(12) Patent Application Publication
(10) Pub. No.: US 2016/0046408 A1
(43) Pub. Date: Feb. 18, 2016

(54) INTERNALLY COATED VESSEL FOR HOUSING A METAL HALIDE

(71) Applicants: L'Air Liquide, Société Anonyme pour l'Etude et l'Exploitation des Procédés Georges Claude, Paris (FR); American Air Liquide, Inc., Fremont, CA (US); Air Liquide Advanced Materials, Inc., Branchburg, NJ (US)

(72) Inventors: Jean-Marc Girard, Houston, TX (US); Glenn Kuchenbeiser, Huston, TX (US); Nicolas Blasco, Houston, TX (US); Vincent Omarjee, Houston, TX (US); Venkateswara Pallem, Houston, TX (US)

(21) Appl. No.: 14/924,623

(22) Filed: Oct. 27, 2015

(51) Int. Cl. B65D 25/14; C23C 16/455; C23C 16/06; B65D 85/00

(52) U.S. Cl. CPC B65D 25/14; B65D 85/70; C23C 16/45555; C23C 16/06

(57) ABSTRACT

Provided is a vessel having internally wettable surfaces therein coated with one or more barrier layers to, for example, inhibit contamination of a material, such as a metal halide, contained in the vessel.

### FIELD OF THE INVENTION

The invention relates to a vessel having internally wettable surfaces coated with one or more barrier layers to, for example, inhibit contamination of a material, such as a metal halide, contained in the vessel.

All documents cited to or relied upon below are expressly incorporated herein by reference.

### BACKGROUND OF THE INVENTION

In many existing and/or emerging industries, such as semiconductor device manufacturing, great importance is placed on strict purity controls for chemicals used in industrial processing. Trace impurities in these chemicals can have a significant impact upon manufactured products and production yields. Thus, semiconductor manufacturing typically requires ultra high pure solids, typically with metal contaminants down to <100 ppb.

The packaging of chemicals can be a significant source of contaminants and impurities. For example, leaching of metal contaminants is an issue when certain chemicals react with the internal surfaces of the vessel in which they are contained. Containment, storage, transportation and delivery is especially challenging for chemicals incorporating halogen groups, such as solid metal halides, since these can be especially corrosive and reactive to the container materials thereby generating impurities that contaminate the product.

One industrial solution has been the use of borosilicate glass for storing reactive materials such as solid metal halides. Borosilicate glass typically shows good chemical etch resistance to these solid metal halides. The use of borosilicate glass, however, is limited by its breakability and inability to make robust high pressure, leak-free connections to other process equipment.

Stainless steel is the material of choice in many industries for storage of reactive chemicals such as solid metal halides. Stainless steel shows good resistance to a wide array of compounds, exhibits high strength and can be formed into a myriad of storage and delivery vessels. It is also compliant with transportation related regulations of such compounds. Unfortunately, however, stainless steel and its related alloys may become corroded by halogen-containing compounds resulting in a leaching of metal impurities, such as iron, copper, manganese, chromium, molybdenum and nickel, which may then contaminate the high purity product stored therein. In addition, metal oxides that form at the surface of the stainless steel, such as Fe₂O₃, Cr₂O₃ and NiO, and which are normally responsible for the inertness of the metal may be etched by the metal halide when heated above room temperature. Similar reactions may occur between a variety of metal halides and the wettable surfaces of metal components housed within the stainless steel container such as trays and distribution plates.

A need exists in the art, therefore, for vessels having improved chemical resistance properties for the handling of reactive chemicals such as solid metal halides.

### SUMMARY OF THE INVENTION

The present invention is directed to a vessel for the containment, storage, transport or delivery of a metal halide composition, comprising one or more interior fluid wettable surfaces comprising one or more barrier layers deposited thereon. In one embodiment, the vessel is a sublimator having one or more metal oxide, metal nitride, metal oxynitride, metal carbonitride or metal oxycarbonitride barrier layers, or combinations thereof, on internal wettable surfaces. The present invention is also directed to a process for producing one or more barrier coatings on an internal wettable surface of a vessel for containment, storage, transport or delivery of a metal halide composition.

### BRIEF DESCRIPTION OF THE FIGURES

FIG. 1 depicts a cross-sectional view of a sublimator coated with one or more barrier layers on the internal wettable surfaces therein.

FIG. 2 is a cross-sectional view of a vessel showing a laminate of two coating layers.

FIG. 3 is a schematic of an atomic layer deposition method that is useful for depositing a barrier layer on internally wettable surfaces of a vessel.

### DETAILED DESCRIPTION OF THE INVENTION

It is to be understood that the figures and descriptions of the present invention have been simplified to illustrate elements that are relevant for a clear understanding of the present invention, while eliminating, for the purpose of clarity, many other elements found in typical systems and arrangements. Those of ordinary skill in the art will recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art. Furthermore, the embodiments identified and illustrated herein are for exemplary purposes only, and are not meant to be exclusive or limited in their description of the present invention.

As mentioned above, metal storage vessels of reactive chemicals may become corroded by halogen-containing compounds housed within them resulting in a leaching of metal impurities. These metal halide byproducts can contaminate the halogen-containing compounds stored in the vessel, compromise the integrity of the vessel itself or affect down stream processes. Stainless steel and its alloys are examples of metal storage vessels which, when in contact with metal halides housed within them, can form volatile metal halide byproducts, two of the most corrosive and volatile being CrO₂Cl₂ and CrO₂F₂. The table below represents other examples of volatile metal chloride byproduct contaminants:

| Compound | M.W. | Volatility |
|---|---|---|
| AlCl₃ | 133.34 | 1 Torr @100° C. |
| MoCl₅ | 273.21 | 1 Torr @120° C. |
| FeCl₃ | 162.20 | 0.75 Torr @190° C. |
| CrCl₂ | 122.90 | N.A. |

The present invention, thus, generally relates to coating the internal wettable surfaces of a vessel housing a solid metal halide composition with one or more barrier layers. The vessel can be used, for example, to contain, store, transport or deliver the solid metal halide composition. In one embodiment, the vessel can be made of stainless steel, although a skilled artisan would readily envision other materials from which the vessel can be made such as nickel, alloys, glass or ceramic. In a particular embodiment, the vessel of the invention having one or more barrier layers coated therein can be a sublimator, such as those described in, for example, U.S. Pat. No. 9,034,105 which is incorporated herein by reference.

As used herein, the term “wettable surface” is the area exposed to the travel path of the chemical component or precursor and/or reactant gas.

As used herein, the term “metal” shall include metalloids. Examples of metalloids include, but are not limited, to B and Si.

The metal halide may be a solid, a liquid or a gas. In one embodiment, the metal halide is a liquid at room temperature such as, for example, TiCl₄. In another embodiment, the metal halide is a solid metal halide.

As used herein, the term “solid metal halide” will encompass halide-containing molecules being solid at room temperature, and having a metal or metalloid center selected from Ti, B, Si, Zr, Hf, V, Nb, Ta, Mo, Cr, W, Al, Ga of several halide ligands being selected from one or different elements (Cl, F, Br, I), and 0, 1 or 2 oxo (═O) ligands. In certain embodiments, the solid metal halide is a tungsten halide, an aluminum halide, a zirconium halide, a hafnium halide, molybdenum halide, a tantalum halide, a vanadium halide, a niobium halide or a titanium halide. In a more particular embodiments, the solid metal halide can be tungsten halide V or VI, such as WCl₅, WCl₆, WBr₅, WBr₆, WI₅ and WI₆, WOCl₄, MoCl₅, MoOCl₄, MoO₂Cl₂, NbCl₅, NbF₅, NbI₅, NbOCl₃, NbOF₃, NbOI₃, HfCl₄, HfF₄, HfI₄, HfBr₄, HfOCl₂, HfOF₂, HfOI₂, HfOBr₂, ZrCl₄, ZrF₄, ZrI₄, ZrBr₄, ZrOCl₂, ZrOI₂, ZrOF₂, ZrOBr₂, TiF₄, TiI₄, TiOCl₂, TiOF₂, VCl₄, VF₅, VI₃, VI₄, VOCl₃, VOF₃, TaF₅, TaCl₅, TaI₅, TaOCl₃, TaOF₃, TaOI₃ or AlCl₃.

As used herein, the term “barrier layer” is interchangeable with the terms “coating layer” and “barrier coating.”

Each of the one or more barrier layers deposited onto the interior wettable surface of the vessel comprises a metal oxide, metal nitride, metal oxynitride, metal carbonitride or metal oxycarbonitride, or combinations thereof. In one embodiment, the metal in the metal oxide, metal nitride, metal oxynitride, metal carbonitride or metal oxycarbonitride, or combinations thereof, in the one or more barrier layers is the same as the metal of the solid metal halide composition being housed in the vessel. For example, the metal can be Ti, B, Si, Zr, Hf, V, Nb, Ta, Mo, Cr, W, Al or Ga or combinations thereof. One of ordinary skill in the art will recognize that the thickness of the barrier layer may vary based on location within the vessel.

In another embodiment of the invention, the vessel can include two or more barrier layers in the form of a laminate. For example, the vessel can include a laminate of a first barrier layer comprising a metal oxide, metal nitride, metal oxynitride, metal carbonitride or metal oxycarbonitride, or combinations thereof, and a second barrier layer comprising a metal oxide, metal nitride, metal oxynitride, metal carbonitride or metal oxycarbonitride, or combinations thereof. The first and second barrier layers may be the same or different. Also, the first and second barrier layers can have the same or different mechanical or corrosion-resistance properties, thereby providing for advantageous properties to the vessel. For example, the laminate composition can be selected to afford optimized etch selectivity to wet etch chemicals such as dilute HF. This can be especially useful for removal of a protective layer which is etch resistant. In addition, the laminate composition can be selected to afford optimized mechanical tensile mismatch between the internal surface of the vessel and the protective layer.

In one embodiment, one to four barrier layers are deposited onto internally wettable surfaces of the vessel. In another embodiment, one or two layers are deposited.

Each of the one or more barrier layers in the internally wettable surfaces of the vessel can be 5 to 1000 nm in thickness. In one embodiment, each of the one or more barrier layers can be 50 to 500 nm in thickness.

The barrier layers may be deposited onto the internal wettable surfaces of the vessel by any means known in the art. Such deposition methods include atomic layer deposition, chemical vapor deposition, molecular layer deposition, plasma-enhanced chemical vapor deposition, plasma-enhanced atomic layer deposition, spray pyrolysis and physical vapor deposition or combinations thereof, all of which are art-recognized. In a particular embodiment, atomic layer deposition can be used as described in “Atomic Layer Deposition: An Overview,” Chem Rev. 110, 111-131 (2010) and “Surface Chemistry of Atomic Layer Deposition: A Case Study for The Trimethylaluminum/Water Process,” Journal of Applied Physics, 97, 121301 (2005) and disclosed in US 2015/01484296, all of which are incorporated herein by reference. Other non-limiting examples of deposition techniques that may be used are found in US 2012/20251797, US 2015/0030885, U.S. Pat. No. 6,511,760, US 2014/0072479 and US 2010/0255198, all of which are expressly incorporated by reference herein.

Thus, the invention also provides for a process for producing one or more barrier coatings on an internal wettable surface of a vessel for containment, storage, transport or delivery of a metal halide composition, comprising the steps of:
determining the metal halide composition to be placed in said vessel;
producing a formulation comprising a metal oxide, metal nitride, metal oxynitride, metal carbonitride or metal oxycarbonitride, or combinations thereof, corresponding to the metal in said metal halide composition;
depositing the formulation onto the one or more interior fluid wettable surfaces of the vessel to form the barrier layer.

As noted above, the material to be deposited onto the internal wettable surface of the vessel can include a metal that matches or is identical to the metal in the metal halide composition to be contained therein. The deposition of this material for the barrier layer, in turn, can be performed using the above-mentioned atomic layer deposition, chemical vapor deposition, molecular layer deposition, plasma-enhanced chemical vapor deposition, plasma-enhanced atomic layer deposition, spray pyrolysis and physical vapor deposition or combinations thereof. In certain embodiments, all or some of the surfaces exposed to the solid metal halide or solid metal halide vapors are coated with the protective barrier layer(s).

Further, the process of producing the vessels of the invention can include pre- and/or post-treatment steps. For example, the process can include, a pre-treatment step prior to deposition onto the interior wettable surfaces. The pre-treatment can include, for example, cleaning the interior wettable surfaces with an organic solvent or dilute acid, mechanical polishing, sand blasting or electrochemical polishing. Other pre-treatment steps known in the art are also contemplated as falling within the invention.

In another embodiment, the process of producing the vessels of the invention can include a post-treatment step after deposition of the one or more barrier layers. The post-treatment can include, for example, thermal annealing with an inert gas, e.g., Ar, He or N₂; oxidizing using a moiety such as, for example, O₂, O₃, H₂O, H₂O₂, NO, N₂O, NO₂, radicals and mixtures thereof; or carburizing using a moiety such as, for example, methane, alkanes, alkenes, alkynes and amines. The invention also contemplates usage of other art-recognized post-treatment processes.

In a particular embodiment, the vessel of the invention includes removable or fixed secondary features having wettable surfaces. Such secondary features include, for example, trays, distribution plates, spargers, beads, heat conduction enhancing features, convoluted flow paths and optical window for on-line metrology or combinations thereof. The invention provides for barrier coatings on these secondary features by the processes disclosed herein. Examples of vessels with secondary features falling within the invention are disclose in U.S. Pat. No. 7,261,118; U.S. Pat. No. 8,137,462; U.S. Pat. No. 8,092,604; US 2014/0174955; U.S. Pat. No. 7,122,085; U.S. Pat. No. 7,547,363, U.S. Pat. No. 7,601,225, U.S. Pat. No. 8,272,626, U.S. Pat. No. 8,603,580 and U.S. Pat. No. 9,034,105, all of which are expressly incorporated herein by reference.

### Representative Embodiments of the Invention

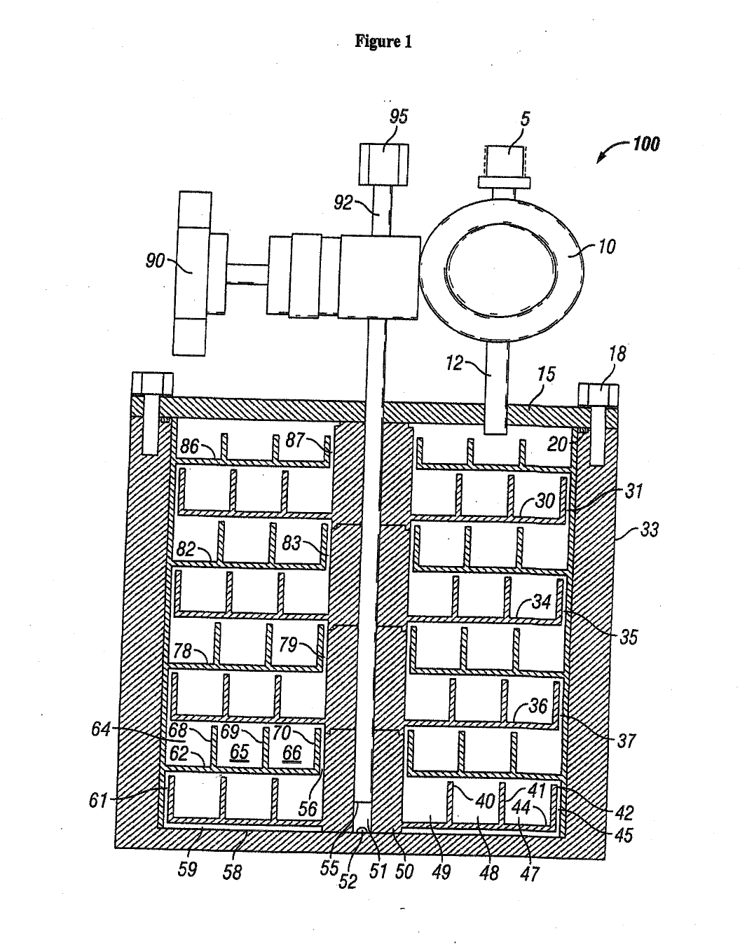

FIG. 1 shows a solid precursor sublimator 100 for subliming a solid precursor such as a solid metal halide. Sublimator 100 comprises interior disks 30, 34, 36, 44 comprising aligned and coupled support legs 50, interior passage 51, concentric walls 40, 41, 42, and concentric slots 47, 48, 49. The interior disks 30, 34, 36, 44 are vertically stacked, and annularly oriented about the dip tube 92. Additionally, the sublimator comprises exterior disks 62, 78, 82, 86. The exterior disks 62, 78, 82, 86 should be tightly fit into the container 33 for a good contact for conducting heat from the container 33 to the disks 62, 78, 82, 86. In these embodiments, the exterior disks 62, 78, 82, 86 are coupled to, or in physical contact with, the inner wall of the container 33. As illustrated, exterior disks 62, 78, 82, 86 and interior disks 30, 34, 36, 44 are stacked inside the container 33. When assembled in container 33 to form sublimator 100, the interior disks 30, 34, 36, 44 form outer gas passages 31, 35, 37, 45 between the assembled exterior disks 62, 78, 82, 86. Further, exterior disks 62, 78, 82, 86 form inner gas passages 56, 79, 83, 87 with the support legs of the interior disks 30, 34, 36, 44. The walls 40, 41, 42 of interior disks 30, 34, 36, 44 form the grooved slots for holding solid precursors. Exterior disks 62, 78, 82, 86 comprise walls 68, 69, 70 for holding solid precursors. During assembly, the solid precursors are loaded into the annular slots 47, 48, 49 of interior disks 30, 34, 36, 44 and annular slots 64, 65, 66 of exterior disks 62, 78, 82, 86.

The sublimator 100 has a plurality of internally wettable surfaces and is configured as a conduit, or contact vessel, for a carrier gas. The sublimator 100 comprises a container 33 having an inner wettable wall and secondary features with wettable surfaces, all of which are suitable for depositing one or more barrier layers thereon. Container 33 is typically a cylindrical container, and alternatively, container 33 may comprise any shape, without limitation. The container 33 is constructed of materials such as stainless steel, nickel and its alloys, quartz, glass, and other chemically compatible materials, without limitation. In certain instances, the container 33 is constructed of another metal or metal alloy, without limitation. In certain instances, the container 33 has an internal diameter from about 8 centimeters to about 55 centimeters and, alternatively, an internal diameter from about 8 centimeters to about 30 centimeters. As understood by one skilled in the art, alternate configurations may have different dimensions.

Container 33 comprises a sealable top 15, sealing member 18, and gasket 20. Sealable top 15 is configured to seal container 33 from the outer environment. Sealable top 15 is configured to allow access to the container 33. Additionally, sealable top 15 is configured for passage of conduits into container 33. Alternatively, sealable top 15 is configured to permit fluid flow into container 33. Sealable top 15 is configured to receive and pass through a conduit comprising a dip tube 92 to remain in fluid contact with container 33. Dip tube 92 having a control valve 90 and a fitting 95 is configured for flowing carrier gas into container 33. In certain instances, dip tube 92 extends down the center axis of container 33. Further, sealable top 15 is configured to receive and pass through a conduit comprising outlet tube 12. The carrier gas is removed from container 33 through the outlet tube 12. Outlet tube 12 comprises a control valve 10 and fitting 5. In certain instances, outlet tube 12 is coupled to a gas delivery manifold, for conducting carrier gas from the sublimator 100 to a film deposition chamber.

Dip tube 92, having the control valve 90 and the fitting 95, is positioned in the center passage 51 of the aligned and coupled support legs of the interior disks 30, 34, 36, 44. Thus, dip tube 92 passes through interior passage 51 vertically′ toward bottom 58 of container 33. The dip tube end 55 is disposed proximal to the bottom 58 of container at/or above the gas windows 52. Gas windows 52 are disposed in bottom interior disk 44. The gas windows 52 are configured to allow carrier gas flow out of the dip tube 92. In the assembled sublimator 100, a gas passageway 59 is formed by the bottom surface 58 of the container 33, and the bottom interior disk 44. In certain instances, gas passageway 59 is configured to heat carrier gas.

In operation, the carrier gas is preheated prior to introduction into the container 33 via dip tube 92. Alternatively, the carrier gas can be heated while it flows through the gas passageway 59 by the bottom surface 58. Bottom surface 58 is thermally coupled and/or heated by an external heater. The carrier gas then passes through the gas passageway 45 that is formed by the outer wall 42 of the interior disk 44 and the outside wall 61 of the exterior disk 62. The gas passageway 45 leads to the top of the interior disk 44, The carrier gas continuously flows over the top of the solid precursors loaded into the annular slots 47, 48, and 49. Sublimed solid vapor from annular slots 47, 48, 49 is mixed with carrier gas and is flowed vertically upward through container 33.

Container 33 and sealable top 15 are sealed by at least two sealing members 18; alternatively, by at least about four sealing members. In certain instance, sealable top 15 is sealed to container 33 by at least about eight sealing members 18. As understood by one skilled in the art, sealing member 18 releasably couples sealable top 15 to container 33, and forms a gas resistant seal with gasket 20. Sealing member 18 may comprise any suitable means known to one skilled in the art for sealing container 33. In certain instances, sealing member 18 comprises a thumbscrew.

As illustrated in FIG. 1, container 33 further comprises secondary features such as at least one disk disposed therein having a wettable surface thereon that can come into contact with the material stored therein such as, for example, a solid metal halide. The disk comprises a shelf, or horizontal support, for solid material. In certain embodiments, an interior disk 30 is disposed annularly within the container 33, such that the disk 30 includes an outer diameter or circumference that is less than the inner diameter or circumference of the container 33, forming an opening 31. Alternatively, an exterior disk 86 is disposed circumferentially within the container 33, such that the disk 86 comprises an outer diameter or circumference that is the same, about the same, or generally coincides with the inner diameter of the container 33. Exterior disk 86 forms an opening 87 disposed at the center of the disk. In further embodiments, a plurality of disks is disposed within container 33. In embodiments, the disks are stacked in an alternating fashion, wherein interior disks 30, 34, 36, 44 are vertically stacked within the container with alternating exterior disks 62, 78, 82, 86. In embodiments, interior disks 30, 34, 36, 44 extend annularly outward, and exterior disks 62, 78, 82, 86 extend annularly toward the center of container 33. As illustrated in the embodiment of FIG. 1, interior disks 30, 34, 36, 44 are not in physical contact with exterior disks 62, 78, 82, 86. All or some of these features can come into contact with a solid metal halide and be a source of contamination if not coated with one or more barrier layers of the invention. In one embodiment, the valves of sublimator 100 are not coated.

Interior disks 30, 34, 36, 44 comprising aligned and coupled support legs 50, interior passage 51, concentric walls 40, 41, 42, and concentric slots 47, 48, 49. The interior disks 30, 34, 36, 44 are vertically stacked, and annularly oriented about the dip tube 92. Additionally, the sublimator comprises exterior disks 62, 78, 82, 86. As illustrated in FIG. 1, the exterior disks 62, 78, 82, 86 should be tightly fit into the container 33 for a good contact for conducting heat from the container 33 to the disks 62, 78, 82, 86. In these embodiments, the exterior disks 62, 78, 82, 86 are coupled to, or in physical contact with, the inner wall of the container 33. As illustrated, exterior disks 62, 78, 82, 86 and interior disks 30, 34, 36, 44 are stacked inside the container 33. When assembled in container 33 to form sublimator 100, the interior disks 30, 34, 36, 44 form outer gas passages 31, 35, 37, 45 between the assembled exterior disks 62, 78, 82, 86. Further, exterior disks 62, 78, 82, 86 form inner gas passages 56, 79, 83, 87 with the support legs of the interior disks 30, 34, 36, 44. The walls 40, 41, 42 of interior disks 30, 34, 36, 44 form the grooved slots for holding solid precursors. Exterior disks 62, 78, 82, 86 comprise walls 68, 69, 70 for holding solid precursors. During assembly, the solid precursors are loaded into the annular slots 47, 48, 49 of interior disks 30, 34, 36, 44 and annular slots 64, 65, 66 of exterior disks 62, 78, 82, 86. And as mentioned above, each of these features can be coated with one or more protective barrier layers to inhibit contamination of the solid metal halide housed therein.

The vessel in FIG. 1 includes interior fluid wetted surfaces therein wherein erosive and/or corrosive process gases and/or fluids can cause deterioration of the interior fluid wetted surfaces and/or cause contaminants from the interior fluid wetted surfaces to be released, thereby causing downstream processing defects and/or substrate contamination of, for example, a semiconductor substrate during semiconductor substrate processing. To alleviate contaminates from interior fluid wetted surfaces of the vessel, the components of the vessel in one embodiment are pre-assembled, vacuum sealed, and configured to form a process space of an atomic layer deposition (ALD) apparatus or a molecular layer deposition (MLD) apparatus wherein ALD or MLD barrier coatings can be formed on the interior fluid wetted surfaces of the vessel.

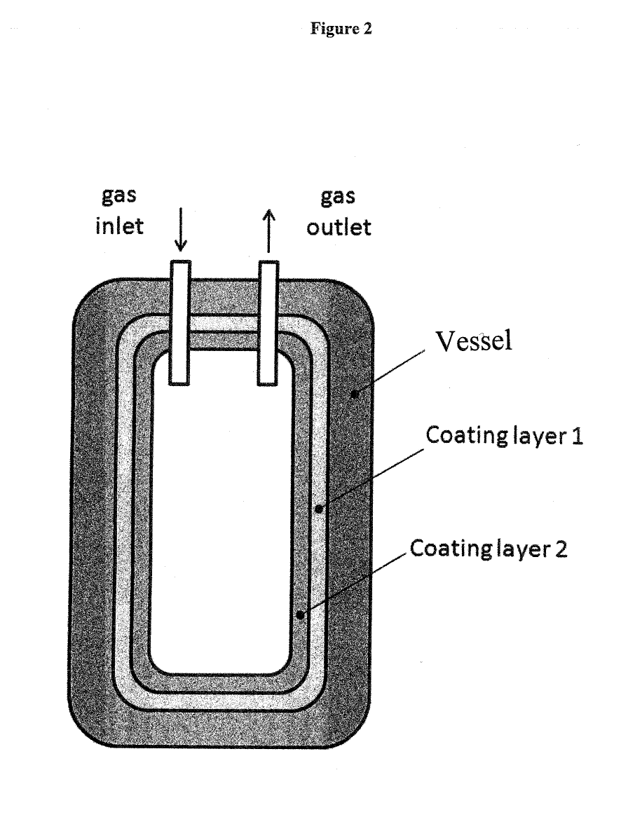

FIG. 2 shows another embodiment of the internally coated vessel of the invention. As shown in FIG. 2, coating layers 1 and 2 are deposited on the internal surface of the vessel. Coating layers 1 and 2 can be the same or different.

The methods of forming the ALD or MLD barrier coating on interior fluid wetted surfaces of the vessel are art-recognized and include, for example, sequentially injecting atomic layer deposition gases or molecular layer deposition gases into an inlet port of the vessel 100 with a gas supply system thereby forming an ALD or MLD barrier coating on the interior fluid wetted surfaces of the vessel 100 and sequentially exhausting the atomic layer deposition gases or the molecular layer deposition gas from an outlet port with an exhaust system wherein the interior fluid wetted surfaces of the vessel form a process region for forming the ALD or MLD barrier coating. For example, the method can include injecting a pulse of a first reactant gas on the interior fluid wetted surfaces of the vessel, and injecting a pulse of a second reactant gas on the interior fluid wetted surfaces of the vessel to react with the first reactant gas to form a layer of the ALD or MLD barrier coating on the interior fluid wetted surfaces of the vessel wherein the method in a particular embodiments includes repeating each injection step (sometimes referred to as a “cycle”) a plurality of times. The method also includes exhausting excess first reactant gas with the exhaust system after injecting the pulse of the first reactant gas, and exhausting excess second reactant gas and reaction byproduct(s) with the exhaust system after dispensing the pulse of the second reactant gas. In one embodiment, the first and second reactant gases are injected into the vessel forming layers of the ALD or MLD barrier coating on the interior fluid wetted surfaces of the vessel until the coating is formed to a desired thickness.

Methods of forming ALD or MLD barrier coatings allow coatings to grow layer-by-layer in a highly precise and controllable manner. Therefore, the thickness of ALD or MLD barrier coatings formed on the interior fluid wetted surfaces of the vessels can be tailored as needed and applied conformally and uniformly over the interior fluid wetted surfaces of the vessel. Further, ALD and MLD processes can deposit pinhole free barrier coatings, thus leading to complete coverage of the interior fluid wetted surfaces of the vessels. A variety of inert materials, such as oxide/nitride/fluoride materials, can be deposited by ALD processes with high coating adhesion on various interior fluid wetted surfaces such as metal surfaces, ceramic surfaces, or temperature-sensitive polymer surfaces of the vessels. In one embodiment, the ALD barrier coating is formed from Al₂O₃. In alternate embodiments, the ALD coating can include at least one of, for example, tantalum (Ta), titanium (Ti), tungsten (W), zirconium (Zr), hafnium (Hf), molybdenum (Mo), niobium (Nb), vanadium (V), ruthenium (Ru) and/or chromium (Cr) and mixtures and/or alloys thereof.

An operator can control the formation of the ALD or MLD barrier coating through interaction with a system controller such as a monitor and a data entry device such as the keyboard. The system controller is employed to control process conditions during deposition, post deposition treatments, and/or other process operations. The controller will typically include one or more memory devices and one or more processors. The processor may include, for example, a CPU or computer, analog and/or digital input/output connections and stepper motor controller boards.

### EXAMPLES

The disclosure is further illustrated by the following examples, which are not to be construed as limiting this disclosure in scope or spirit to the specific procedures herein described. It is to be understood that the examples are provided to illustrate certain embodiments and that no limitation to the scope of the disclosure is intended thereby. It is to be further understood that resort may be had to various other embodiments, modifications, and equivalents thereof which may suggest themselves to those skilled in the art without departing from the spirit of the present disclosure and/or scope of the appended claims.

### Example 1

### Single-Component Barrier Layer

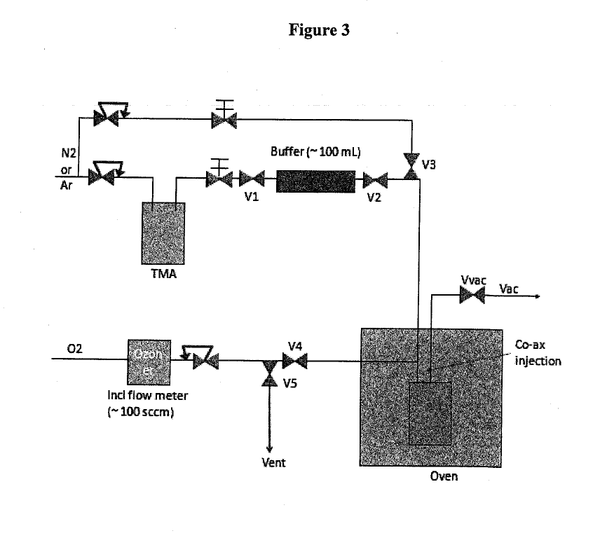

FIG. 3 is a schematic of a representative ALD procedure for the internal coating of a sublimator housing a solid metal halide precursor. As shown in FIG. 3, the deposition by ALD of an Al₂O₃ coating using trimethylaluminium (TMA) and O₂/O₃ on the internally wettable surfaces of the vessel includes the following steps:
Startup & purge mode:
   Flow O₃ through bypass with valve V4 closed and valve V5 open;
   Fill buffer with TMA vapor with valve V1 open and V2 closed;
   Initiate dynamic vacuum of vessel with both vacuum valve Vvac and valve V3 open; and
   Set oven at 250° C.
Deposition of the Al₂O₃ coating:
   Close valve V3→Full vac in vessel
   Close vacuum valve Vvac→seal under vacuum
   Close valve V1, open valve V2→TMA pulse (static) in vessel
   Close valve V2, open valve V1, open vacuum valve Vvac, open valve V3→flush excess TMA
   Close valve V5, open valve V4→Flow O₃ (dynamic oxidation)
   Close valve V4, open valve V5→divert O₃, N₂ flush
   Cycle at least 100 times until desired thickness of the layer is reached. The coating thickness will be approximately 0.1 nm/cycle.

### Example 2

### Bi-Component Laminate

By adding an additional precursor source and using the schematic of FIG. 3 as described in Example 1, a laminate of Ta₂O₅ on SiO₂ can be deposited by atomic layer deposition, with layer thicknesses ranging from nm level to above 500 nm level. A 50 nm SiO₂ layer underneath a 100 nm Ta₂O₅ layer will enable removal of the Ta₂O₅ protecting layer by known methods such as dilute HF exposure, for subsequent re-coating with a new fresh SiO₂/Ta₂O₅ stack layer. Such a Ta₂O₅ layer can for instance be deposited by ALD from TAETO (Ta(OEt)₅), TBTDET (Ta(=NtBu)(NEt₂)₃), TBTEMT (Ta(=NtBu)(NEtMe)₃). Therefore, using a SiO₂ protective and sacrificial layer underneath will improve manufacturability and performance of the vessel.

### Example 3

### Comparative Analysis

An electropolished stainless steel vessel with appropriate valves was heated to 150° C. under a vacuum for a variable time, and another similar vessel was coated with 100 nm of an SiON coating deposited by plasma-enhanced chemical vapor deposition. Both vessels were filled with solid WCl₅ to less than ½ of the total volume. Using Inductively Coupled Plasma Mass Spectroscopy (ICP-MS), the metal contamination in the vessels were measured after several time intervals and recorded in the table below (wherein ppb=ppbw):

| | | | Coated Ampoules | | | | SS Ampoule |
|---|---|---|---|---|---|---|---|
| | DL | Unit | 0 week | 1 week | 2 weeks | 4 weeks | 4 weeks |
| Aluminum (Al) | 150 | ppb | <150 | <150 | <150 | <150 | <150 |
| Antimony (Sb) | 150 | ppb | <150 | <150 | <150 | <150 | <150 |
| Arsenic (As) | 150 | ppb | <150 | <150 | 600 | <150 | <150 |
| Barium (Ba) | 150 | ppb | <150 | <150 | <150 | <150 | <150 |
| Beryllium (Be) | 150 | ppb | <150 | <150 | <150 | <150 | <150 |
| Cadmium (Cd) | 150 | ppb | <150 | <150 | <150 | <150 | <150 |
| Calcium (Ca) | 150 | ppb | <150 | <150 | <150 | <150 | <150 |
| Chromium (Cr) | 150 | ppb | <150 | <150 | <150 | <150 | 620 |
| Cobalt (Co) | 150 | ppb | <150 | <150 | <150 | <150 | <150 |
| Copper (Cu) | 150 | ppb | <150 | <150 | <150 | <150 | 460 |
| Gallium (Ga) | 150 | ppb | <150 | <150 | <150 | <150 | <150 |
| Germanium (Ge) | 150 | ppb | <150 | <150 | <150 | <150 | <150 |
| Indium (In) | 150 | ppb | <150 | <150 | <150 | <150 | <150 |
| Iron (Fe) | 150 | ppb | <150 | <150 | 700 | 130 | 3000 |
| Lead (Pb) | 150 | ppb | <150 | <150 | <150 | <150 | <150 |
| Lithium (Li) | 150 | ppb | <150 | <150 | <150 | <150 | <150 |
| Magnesium (Mg) | 150 | ppb | <150 | <150 | <150 | <150 | <150 |
| Manganese (Mn) | 150 | ppb | <150 | <150 | <150 | <150 | <150 |
| Molybdenum (Mo) | 150 | ppb | <150 | <150 | <150 | <150 | <150 |
| Nickel (Ni) | 150 | ppb | <150 | <150 | <150 | <150 | 1200 |
| Niobium (Nb) | 150 | ppb | 180 | <150 | <150 | 160 | 210 |
| Potassium (K) | 150 | ppb | <150 | <150 | <150 | <150 | <150 |
| Sodium (Na) | 150 | ppb | <150 | <150 | <150 | <150 | <150 |
| Strontium (Sr) | 150 | ppb | <150 | <150 | <150 | <150 | <150 |
| Tin (Sn) | 150 | ppb | <150 | <150 | <150 | <150 | <150 |
| Titanium (Ti) | 150 | ppb | <150 | <150 | <150 | <150 | <150 |
| Vanadium (V) | 150 | ppb | <150 | <150 | <150 | <150 | <150 |
| Zinc (Zn) | 150 | ppb | <150 | <150 | <150 | <150 | <150 |
| Zirconium (Zr) | 150 | ppb | <150 | <150 | <150 | <150 | <150 |

As seen in the table above, a clear increase in metal contamination was observed for the non-coated vessel.

### Example 4

### Long-Term Storage of Solid Metal Halide in Coated Vessel

An electropolished stainless steel vessel with appropriate valves is heated to 300° C. under a vacuum for 4 hours. The vessel internal surfaces are subsequently coated using an atomic layer deposition process to afford a thickness of 300 nm of a tungsten oxide film. The vessel is loaded with a high purity tungsten chloride composition which remains free of metallic impurities during the course of 12 months in storage at ambient conditions.

The invention is further described by the following numbered paragraphs:

1. A vessel for containment, storage, transport or delivery of a metal halide composition, comprising one or more interior fluid wettable surfaces comprising one or more barrier layers deposited thereon, wherein each of said layers may be the same or different.

2. The vessel according to paragraph 1, wherein said vessel is a sublimator.

3. The vessel according to paragraph 1, wherein each of said one or more barrier layers comprises a metal oxide, metal nitride, metal oxynitride, metal carbonitride or metal oxycarbonitride, or combinations thereof.

4. The vessel according to paragraph 3, wherein the metal in said one or more barrier layers is the same as the metal of said metal halide composition.

5. The vessel according to paragraph 3, wherein said metal is Ti, B, Si, Zr, Hf, V, Nb, Ta, Mo, Cr, W, Al or Ga.

6. The vessel according to paragraph 1, wherein the metal halide is a solid.

7. The vessel according to paragraph 1, wherein the metal halide is a tungsten halide, an aluminum halide, a zirconium halide, a hafnium halide, molybdenum halide, a tantalum halide, a vanadium halide, a niobium halide or a titanium halide.

8. The vessel according to paragraph 1, comprising a laminate of a first barrier layer comprising a metal oxide, metal nitride, metal oxynitride, metal carbonitride or metal oxycarbonitride, or combinations thereof, and a second barrier layer comprising a metal oxide, metal nitride, metal oxynitride, metal carbonitride or metal oxycarbonitride, or combinations thereof.

9. The vessel according to paragraph 8, wherein said first and second barrier layers have the same or different mechanical or corrosion-resistance properties.

10. The vessel according to paragraph 1, wherein each of said one or more barrier layers is 5 to 1000 nm in thickness.

11. The vessel according to paragraph 1, wherein each of said one or more barrier layers is 50 to 500 nm in thickness.

12. The vessel according to paragraph 1, wherein one to four barrier layers are deposited.

13. The vessel according to paragraph 1, wherein one or two barrier layers are deposited.

14. The vessel according to paragraph 2, wherein said sublimator comprises valves.

15. The vessel according to paragraph 14, wherein said valves are not coated with a barrier layer.

16. The vessel according to paragraph 1, wherein the solid metal halide is WCl₅, WCl₆, WBr₅, WBr₆, WI₅, WI₆, WOCl₄, MoCl₅, MoOCl₄, MoO₂Cl₂, NbCl₅, NbF₅, NbI₅, NbOCl₃, NbOF₃, NbOI₃, HfCl₄, HfF₄, HfI₄, HfBr₄, HfOCl₂, HfOF₂, HfOI₂, HfOBr₂, ZrCl₄, ZrF₄, ZrI₄, ZrBr₄, ZrOCl₂, ZrOI₂, ZrOF₂, ZrOBr₂, TiF₄, TiI₄, TiOCl₂, TiOF₂, VCl₄, VF₅, VI₃, VI₄, VOCl₃, VOF₃, TaF₅, TaCl₅, TaI₅, TaOCl₃, TaOF₃, TaOI₃ or AlCl₃.

17. A vessel for containment, storage, transport or delivery of a solid metal halide composition, said vessel comprising one or more interior fluid wettable surfaces comprising one or more barrier layers made by a process selected from the group consisting of atomic layer deposition, chemical vapor deposition, molecular layer deposition, plasma-enhanced chemical vapor deposition, plasma-enhanced atomic layer deposition, spray pyrolysis and physical vapor deposition or combinations thereof.

18. The vessel according to paragraph 17, wherein said process further comprises a post-deposition curing of said one or more barrier layers.

19. The vessel according to paragraph 18, wherein said post-deposition curing is selected from the group consisting of firing, thermal annealing, UV curing, thermal oxidation, carbidation and laser curing.

20. The vessel according to paragraph 1, further comprising a removable or fixed secondary feature comprising one or more of said barrier layers deposited thereon.

21. The vessel according to paragraph 20, wherein said secondary feature is selected from the group consisting of trays, distribution plates, spargers, beads, heat conduction enhancing features, convoluted flow paths and optical window for on-line metrology or combinations thereof.

22. A method for producing one or more barrier layers on an internal wettable surface of a vessel for containment, storage, transport or delivery of a metal halide composition, comprising the steps of:
determining the metal halide composition to be placed in said vessel;
producing a formulation comprising a metal oxide, metal nitride, metal oxynitride, metal carbonitride or metal oxycarbonitride, or combinations thereof, corresponding to the metal in said metal halide composition;
depositing said formulation onto said one or more interior fluid wettable surfaces of said vessel to form said barrier layer.

23. The method according to paragraph 22, wherein said depositing step is performed using atomic layer deposition, chemical vapor deposition, molecular layer deposition, plasma-enhanced chemical vapor deposition, plasma-enhanced atomic layer deposition, spray pyrolysis and physical vapor deposition or combinations thereof 24. The method according to paragraph 22, wherein said depositing step is performed using atomic layer deposition or chemical vapor deposition.

25. The method according to paragraph 22, further comprising a pre-treatment step prior to deposition onto said interior wettable surfaces, wherein said pre-treatment is cleaning said interior wettable surfaces with an organic solvent or dilute acid, mechanical polishing, sand blasting or electrochemical polishing.

26. The method according to paragraph 22, further comprising a post-treatment step after said barrier layer is deposited, wherein said post-treatment is thermal annealing with an inert gas, oxidizing or carburizing.

27. The method according to paragraph 26, wherein said inert gas Ar, He or N₂.

28. The method according to paragraph 26, wherein said oxidizing uses a moiety selected from the group consisting of O₂, O₃, H₂O, H₂O₂, NO, N₂O, NO₂, radicals and mixtures thereof.

29. The method according to paragraph 26, wherein said carburizing uses a moiety selected from the group consisting of methane, alkanes, alkenes, alkynes and amines.

30. The method according to paragraph 22, further comprising the barrier layer maintaining the copper concentration of the metal halide composition between 0 ppmw and 150 ppmw as determined by ICP-MS.

31. The method according to paragraph 22, further comprising the barrier layer maintaining the nickel concentration of the metal halide composition between 0 ppmw and 150 ppmw as determined by ICP-MS.

It is to be understood that the invention is not limited to the particular embodiments of the invention described above, as variations of the particular embodiments may be made and still fall within the scope of the appended claims.

1. A vessel for containment, storage, transport or delivery of a metal halide composition, comprising one or more interior fluid wettable surfaces comprising one or more barrier layers deposited thereon, wherein each of said layers may be the same or different.

2. The vessel according to claim 1, wherein said vessel is a sublimator.

3. The vessel according to claim 1, wherein each of said one or more barrier layers comprises a metal oxide, metal nitride, metal oxynitride, metal carbonitride or metal oxycarbonitride, or combinations thereof.

4. The vessel according to claim 3, wherein the metal in said one or more barrier layers is the same as the metal of said metal halide composition.

5. The vessel according to claim 3, wherein said metal is Ti, B, Si, Zr, Hf, V, Nb, Ta, Mo, Cr, W, Al or Ga.

6. The vessel according to claim 1, wherein the metal halide is a solid.

7. The vessel according to claim 1, wherein the metal halide is a tungsten halide, an aluminum halide, a zirconium halide, a hafnium halide, molybdenum halide, a tantalum halide, a vanadium halide, a niobium halide or a titanium halide.

8. The vessel according to claim 1, comprising a laminate of a first barrier layer comprising a metal oxide, metal nitride, metal oxynitride, metal carbonitride or metal oxycarbonitride, or combinations thereof, and a second barrier layer comprising a metal oxide, metal nitride, metal oxynitride, metal carbonitride or metal oxycarbonitride, or combinations thereof.

9. The vessel according to claim 1, wherein each of said one or more barrier layers is 5 to 1000 nm in thickness.

10. The vessel according to claim 1, wherein each of said one or more barrier layers is 50 to 500 nm in thickness.

11. The vessel according to claim 2, wherein said sublimator comprises valves.

12. The vessel according to claim 11, wherein said valves are not coated with a barrier layer.

13. The vessel according to claim 1, wherein the metal halide is WCl₅, WCl₆, WBr₅, WBr₆, WI₅, WI₆, WOCl₄, MoCl₅, MoOCl₄, MoO₂Cl₂, NbCl₅, NbF₅, NbI₅, NbOCl₃, NbOF₃, NbOI₃, HfCl₄, HfF₄, HfI₄, HfBr₄, HfOCl₂, HfOF₂, HfOI₂, HfOBr₂, ZrCl₄, ZrF₄, ZrI₄, ZrBr₄, ZrOCl₂, ZrOI₂, ZrOF₂, ZrOBr₂, TiCl₄, TiF₄, TiI₄, TiOCl₂, TiOF₂, VCl₄, VF₅, VI₃, VI₄, VOCl₃, VOF₃, TaF₅, TaCl₅, TaI₅, TaOCl₃, TaOF₃, TaOI₃ or AlCl₃.

14. A vessel for containment, storage, transport or delivery of a solid metal halide composition, said vessel comprising one or more interior fluid wettable surfaces comprising one or more barrier layers made by a process selected from the group consisting of atomic layer deposition, chemical vapor deposition, molecular layer deposition, plasma-enhanced chemical vapor deposition, plasma-enhanced atomic layer deposition, spray pyrolysis and physical vapor deposition or combinations thereof.

15. The vessel according to claim 1, further comprising a removable or fixed secondary feature comprising one or more of said barrier layers deposited thereon.

16. The vessel according to claim 15, wherein said secondary feature is selected from the group consisting of trays, distribution plates, spargers, beads, heat conduction enhancing features, convoluted flow paths and optical window for on-line metrology or combinations thereof.

17. A method for producing one or more barrier layers on an internal wettable surface of a vessel for containment, storage, transport or delivery of a metal halide composition, comprising the steps of:
determining the metal halide composition to be placed in said vessel;
producing a formulation comprising a metal oxide, metal nitride, metal oxynitride, metal carbonitride or metal oxycarbonitride, or combinations thereof, corresponding to the metal in said metal halide composition;
depositing said formulation onto said one or more interior fluid wettable surfaces of said vessel to form said barrier layer.

18. The method according to claim 17, wherein said depositing step is performed using atomic layer deposition, chemical vapor deposition, molecular layer deposition, plasma-enhanced chemical vapor deposition, plasma-enhanced atomic layer deposition, spray pyrolysis and physical vapor deposition or combinations thereof.

19. The method according to claim 17, further comprising a pre-treatment step prior to deposition onto said interior wettable surfaces, wherein said pre-treatment is cleaning said interior wettable surfaces with an organic solvent or dilute acid, mechanical polishing, sand blasting or electrochemical polishing.

20. The method according to claim 17, further comprising a post-treatment step after said barrier layer is deposited, wherein said post-treatment is thermal annealing with an inert gas, oxidizing or carburizing.
